(19) United States
(12) Patent Application Publication
(10) Pub. No.: US 2025/0183241 A1
(43) Pub. Date: Jun. 5, 2025

(54) SEMICONDUCTOR PACKAGE

(71) Applicant: Samsung Electronics Co., Ltd., Suwon-si (KR)

(72) Inventors: Hyunsoo Chung, Suwon-si (KR); Inyoung Lee, Suwon-si (KR)

(21) Appl. No.: 18/914,470

(22) Filed: Oct. 14, 2024

(30) Foreign Application Priority Data
Nov. 30, 2023 (KR) 10-2023-0171834

(51) Int. Cl. H01L 25/16; G02B 6/12; H01L 23/31; H01L 23/48; H01L 23/538

(52) U.S. Cl. CPC H01L 25/167; G02B 6/12002; H01L 23/5385; H01L 23/3107; H01L 23/481

(57) ABSTRACT

A semiconductor package includes a package substrate including a first waveguide, a PIC chip on the package substrate and including a second waveguide, a first molding layer on the package substrate and surrounding the PIC chip, an electronic integrated circuit (EIC) chip arranged on the first molding layer and the PIC chip to vertically overlap both the first molding layer and the PIC chip, a semiconductor chip on the PIC chip, and a plurality of stack structures arranged horizontally apart from each other on the first molding layer and the PIC chip, wherein the first waveguide is disposed on an upper surface of the package substrate, and wherein the PIC chip is arranged on the package substrate such that a surface of the PIC chip, adjacent to the second waveguide, faces the package substrate.

### CROSS-REFERENCE TO RELATED APPLICATION

This application is based on and claims priority under 35 U.S.C. § 119 to Korean Patent Application No. 10-2023-0171834, filed on Nov. 30, 2023, in the Korean Intellectual Property Office, the disclosure of which is incorporated by reference herein in its entirety.

### BACKGROUND

The inventive concept relates to a semiconductor package, and more particularly, to a semiconductor package including a photonic integrated circuit (PIC) chip.

Electronic devices are increasingly utilizing the advantages of semiconductor packages to improve functionality and integrate components. In a semiconductor package, various integrated circuits, such as memory chips or logic chips, may be mounted on a package substrate. Recently, in an environment in which data traffic increases in data centers and communication infrastructures, research onto semiconductor packages including PIC chips has continued.

### SUMMARY

Aspects of the inventive concept provide a semiconductor package capable of preventing failures in a photonic integrated circuit (PIC) chip.

Aspects of the inventive concept provide a semiconductor package with a short signal transmission distance.

Technical problems to be solved by the inventive concept are not limited to the above description, and other technical problems may be clearly understood by one of ordinary skill in the art from the descriptions provided hereinafter.

According to an aspect of the inventive concept, a semiconductor package includes a package substrate including a first waveguide, a PIC chip on the package substrate and including a second waveguide, a first molding layer on the package substrate and surrounding the PIC chip, an electronic integrated circuit (EIC) chip arranged on the first molding layer and the PIC chip to vertically overlap both the first molding layer and the PIC chip, a semiconductor chip on the PIC chip, and a plurality of stack structures arranged horizontally apart from each other on the first molding layer and the PIC chip, wherein the first waveguide is disposed on an upper surface of the package substrate, and wherein the PIC chip is arranged on the package substrate such that a surface of the PIC chip, adjacent to the second waveguide, faces the package substrate.

According to another aspect of the inventive concept, a semiconductor package includes a package substrate including a first waveguide, a PIC chip on the package substrate and including a second waveguide, a first molding layer on the package substrate and surrounding the PIC chip, an EIC chip arranged on the first molding layer and the PIC chip to vertically overlap both the first molding layer and the PIC chip, a semiconductor chip arranged on the first molding layer and the PIC chip, a plurality of stack structures arranged horizontally apart from each other on the first molding layer, and a second molding layer arranged on the first molding layer and surrounding the plurality of stack structures, the semiconductor chip, and the EIC chip, wherein the first waveguide of the package substrate is arranged adjacent to an upper surface of the package substrate, the second waveguide of the PIC chip is arranged adjacent to a lower surface of the PIC chip, and the PIC chip overlaps the semiconductor chip and the EIC chip in a vertical direction.

According to another aspect of the inventive concept, a semiconductor package including a package substrate includes a first waveguide, a PIC chip on the package substrate and including a second waveguide, a first molding layer on the package substrate and surrounding the PIC chip, a redistribution layer on the PIC chip and the first molding layer, an EIC on the redistribution layer, a semiconductor chip on the redistribution layer and spaced apart from the EIC chip in a horizontal direction, and a plurality of stack structures arranged on the redistribution layer and spaced apart from the EIC chip and the semiconductor chip in a horizontal direction. The first waveguide disposed adjacent to an upper surface of the package substrate, the second waveguide is disposed on a lower surface of the PIC chip, a portion of the first waveguide faces a portion of the second waveguide, and the plurality of stack structures and the EIC chip are arranged to surround the semiconductor chip.

### BRIEF DESCRIPTION OF THE DRAWINGS

Embodiments will be more clearly understood from the following detailed description taken in conjunction with the accompanying drawings in which:

FIG. 1 is a schematic plan view of a semiconductor package according to an embodiment;

FIG. 2 is a schematic cross-sectional view of the semiconductor package of FIG. 1, taken along a line A-A′ of FIG. 1;

FIG. 3 is an n enlarged schematic cross-sectional view of a region EX1 of the semiconductor package of FIG. 2;

FIG. 4 is an n enlarged schematic cross-sectional view of a region EX2 of the semiconductor package of FIG. 2;

FIG. 5 is a schematic cross-sectional view of a semiconductor package according to an embodiment, taken along the line A-A′ of FIG. 1;

FIG. 6 is a schematic cross-sectional view of a semiconductor package according to an embodiment, taken along the line A-A′ of FIG. 1;

FIG. 7 is a schematic cross-sectional view of a semiconductor package according to an embodiment, taken along the line A-A′ of FIG. 1;

FIG. 8 is a schematic plan view of a semiconductor package according to an embodiment;

FIG. 9 is a schematic cross-sectional view of the semiconductor package of FIG. 8, taken along a line B-B′ of FIG. 8;

FIG. 10 is an enlarged schematic cross-sectional view of a region EX3 of the semiconductor package of FIG. 8; and

FIG. 11 is a schematic plan view of a semiconductor package according to an embodiment.

### DETAILED DESCRIPTION OF THE EMBODIMENTS

As the disclosure allows for various changes and numerous embodiments, particular embodiments will be shown in the drawings and described in detail in the written description. However, the detailed description is not intended to limit the present embodiments to specific embodiments.

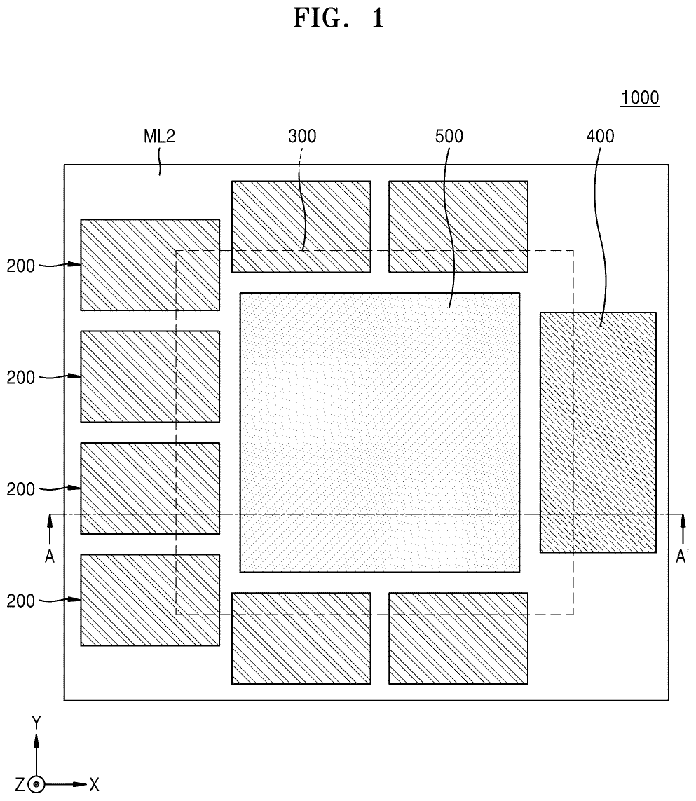

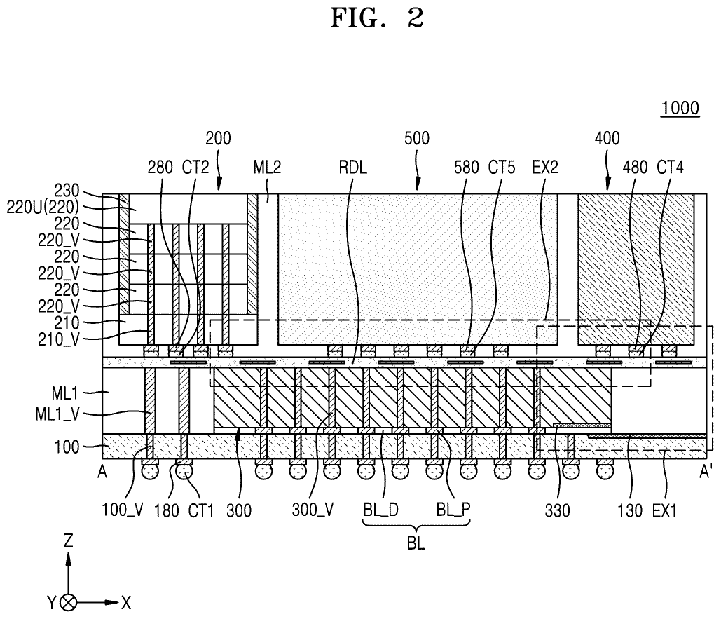

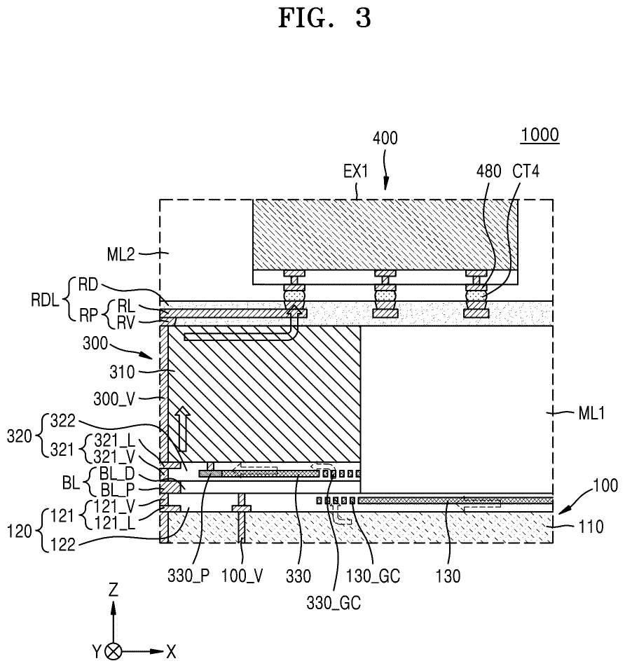

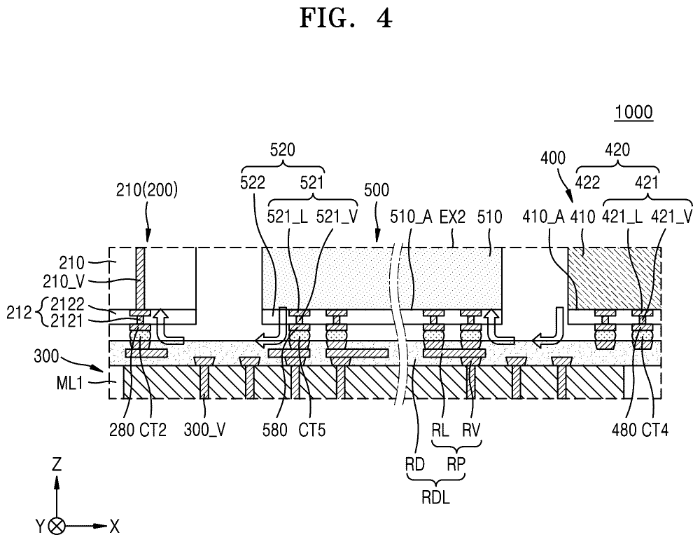

FIG. 1 is a schematic plan view of a semiconductor package 1000 according to an embodiment. FIG. 2 is a schematic cross-sectional view of the semiconductor package 1000 of FIG. 1, taken along a line A-A′ of FIG. 1. FIG. 3 is an enlarged schematic cross-sectional view of a region EX1 of the semiconductor package 1000 of FIG. 2. FIG. 4 is an enlarged schematic cross-sectional view of a region EX2 of the semiconductor package 1000 of FIG. 2.

Referring to FIGS. 1 to 4, the semiconductor package 1000 may include a package substrate 100, a photonic integrated circuit (PIC) chip 300, a first molding layer ML1, an electronic integrated circuit (EIC) chip 400, a semiconductor chip 500, and a plurality of stack structures 200.

Hereinafter, unless otherwise specifically defined, a direction parallel to an upper surface of the package substrate 100 may be defined as a first horizontal direction (an X direction), a direction perpendicular to the upper surface of the package substrate 100 may be defined as a vertical direction (a Z direction), and a direction perpendicular to the first horizontal direction (the X direction) and the vertical direction (the Z direction) may be defined as a second horizontal direction (a Y direction). A combination of the first horizontal direction (the X direction) and the second horizontal direction (the Y direction) is defined as the horizontal direction.

The package substrate 100 may be an interposer including a first substrate 110 and a first through via 100_V (e.g., plurality of first through vias 100_V) penetrating the first substrate 110. For example, the package substrate 100 may be a glass interposer in which the first substrate 110 includes glass and the first through via 100_V is a through glass via (TGV). However, one or more embodiments are not limited thereto. The package substrate 100 may be a silicon interposer in which the first substrate 110 includes silicon (Si) and the first through via 100_v is a through silicon via (TSV). Throughout this specification, items described in the singular (e.g., a first through via 100_v) may be provided in plural, particularly when depicted as such in the drawings, or as otherwise may be evident based on the context in which they are described.

In some embodiments, the package substrate 100 may further include a first wiring structure 120 and a first waveguide 130. The first wiring structure 120 and the first waveguide 130 may be arranged on an upper surface of the first substrate 110. For example, the first wiring structure 120 and the first waveguide 130 may face the PIC chip 300 and/or the first molding layer ML1, to be between the first substrate 110, and the PIC chip 300 and/or the first molding layer ML1.

The first wiring structure 120 may include a first wiring pattern 121 and a first wiring insulating layer 122 surrounding the first wiring pattern 121. The first wiring pattern 121 may include a first wiring line 121_L (e.g., a plurality of first wiring lines 121_L) extending in the horizontal direction and a first wiring via 121_V (e.g., a plurality of first wiring vias 121_V) extending from the first wiring line 121_L (e.g., extending from the plurality of first wiring lines 121_L) in the vertical direction (the Z direction).

The first waveguide 130 may be buried in the first wiring structure 120. For example, an upper surface of the first waveguide 130 may be spaced apart from an upper surface of the first wiring insulating layer 122, and a lower surface of the first waveguide 130 may be spaced apart from a lower surface of the first wiring insulating layer 122. In this embodiment, the first waveguide is completely buried in and covered by (e.g., on both top and bottom surfaces) the first wiring insulating layer 122. In some embodiments, the first waveguide 130 may be covered by an oxide layer distinguished from the first wiring insulating layer 122. However, one or more embodiments are not limited thereto, and the first waveguide 130 may be variously designed according to necessity.

In some embodiments, the first waveguide 130 may be a patterned silicon layer. For example, the first waveguide 130 may be a silicon waveguide, and the first wiring insulating layer 122 may be a buried oxide (BOX) layer. In some embodiments, when the package substrate 100 is a glass interposer, the first waveguide 130 may be an ion injection waveguide.

In some embodiments, the package substrate 100 may be a redistribution structure including a redistribution pattern and a redistribution insulating layer surrounding the redistribution pattern. In some embodiments, the package substrate 100 may be a printed circuit board (PCB) that includes a core insulating layer including at least one material selected from among phenol resin, epoxy resin, and polyimide.

The package substrate 100 may include lower pads 180 on the lower surface of the package substrate 100. In some embodiments, the lower pads 180 may be electrically connected to the first through vias 100_V. In some embodiments, the lower pads 180 may include or be formed of copper (Cu), nickel (Ni), stainless steel, or beryllium copper.

External connection terminals CT1 may be respectively attached to the lower pads 180. The external connection terminals CT1 may be configured to electrically and physically connect the package substrate 100 to an external device in which the package substrate 100 is mounted. The external connection terminals CT1 may be formed from, for example, solder balls or solder bumps.

However, the embodiments are not limited thereto, and the package substrate 100 may be mounted in a socket in an external device. For example, the package substrate 100 may be electrically and physically connected to the external device without the external connection terminals CT1.

The PIC chip 300 may be arranged on the package substrate 100. The PIC chip 300 may be located above a central region of the package substrate 100. For example, all side surfaces of the PIC chip 300 may be arranged on the upper surface of the package substrate 100, so that each side surface overlaps the package substrate in a vertical direction.

The PIC chip 300 may include a second substrate 310, a second wiring structure 320, and a second waveguide 330. For example, the second substrate 310 may include a second through via 300_V (e.g., plurality of second through vias 300_V) extending from an upper surface of the second substrate 310 to a lower surface thereof. The second through via 300_V may be electrically connected to the second wiring structure 320 and/or a redistribution layer RDL. It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

The second wiring structure 320 and the second waveguide 330 may be arranged on the lower surface of the second substrate 310. The PIC chip 300 may be arranged on the package substrate 100 so that the second wiring structure 320 and the second waveguide 330 (e.g., external surfaces of the second wiring structure 320 and second waveguide 330) face the package substrate 100.

In some embodiments, the second substrate 310 may include or be formed of a semiconductor material, such as Si. Alternatively, the second substrate 310 may include or be formed of a semiconductor material, such as germanium (Ge).

The second wiring structure 320 may include a second wiring pattern 321 and a second wiring insulating layer 322 surrounding the second wiring pattern 321. The second wiring pattern 321 may include a second wiring line 321_L (e.g., a plurality of second wiring lines 321_L) extending in the horizontal direction and a second wiring via 321_V (e.g., a plurality of second wiring vias 321_V) extending from the second wiring line 321_L (e.g., the plurality of second wiring lines 321_L) in the vertical direction (the Z direction). The second wiring pattern 321 may be electrically connected to the second through vias 300_V.

The second waveguide 330 may be buried in the second wiring structure 320. For example, an upper surface of the second waveguide 330 may be spaced apart from an upper surface of the second wiring insulating layer 322, and a lower surface of the second waveguide 330 may be spaced apart from a lower surface of the second wiring insulating layer 322. In some embodiments, the second waveguide 330 may be covered by an oxide layer distinguished from the second wiring insulating layer 322. However, the embodiments are not limited thereto, and the second waveguide 330 may be variously designed according to necessity.

In some embodiments, the second waveguide 330 may be a patterned silicon layer. For example, the second waveguide 330 may be a silicon waveguide, and the second wiring insulating layer 322 may be a BOX layer.

The second waveguide 330 may be connected to a photonic component 330_P (e.g., a plurality of photonic components). The photonic component 330_P may convert an optical signal into an electrical signal and an electrical signal into an optical signal. In some embodiments, the photonic component 330_P may include a photodetector, laser diodes, and a modulator.

In the process whereby an optical signal is input to the PIC chip 300, the photodetector may detect the optical signal that is input to the PIC chip 300. The PIC chip 300 may detect the optical signal input through the photodetector and may convert the same into an electrical signal.

While the PIC chip 300 outputs the optical signal, the EIC chip 400 may transmit the electrical signal to the modulator. The modulator may input a signal corresponding to a received electrical signal into light emitted from the laser diode and may convert the electrical signal into an optical signal.

Referring to FIG. 3, the first waveguide 130 of the package substrate 100 and the second waveguide 330 of the PIC chip 300 may overlap each other in the vertical direction (the Z direction). At least a portion of the first waveguide 130 and at least a portion of the PIC chip 300 may overlap each other in the vertical direction (the Z direction) and face each other.

The first waveguide 130 may be optically connected to the second waveguide 330. The first waveguide 130 and the second waveguide 330 may be optically connected to each other through a grating coupler or an evanescent coupler. However, the method by which the first waveguide 130 is optically connected to the second waveguide 330 is not limited thereto.

In some embodiments, the first waveguide 130 may further include a first grating coupler 130_GC, and the second waveguide 330 may further include a second grating coupler 330_GC. The first grating coupler 130_GC may be in a portion of the first waveguide 130 that faces the second waveguide 330, and the second grating coupler 330_GC may be in a portion of the second waveguide 330 that faces the first waveguide 130 such that the first grating coupler 130_GC may face the second grating coupler 330_GC.

The first waveguide 130 may extend to the outside of the PIC chip 300. For example, the first waveguide 130 may extend to a side surface of the package substrate 100 and be optically connected to optical fiber spaced apart from the PIC chip 300. The first waveguide 130 may be configured to transmit, to the second waveguide 330, the optical signal transmitted through the optical fiber. Accordingly, the PIC chip 300 may be buried in the first molding layer ML1 and receive/transmit the optical signal from/to the outside of the package 1000 through the first waveguide 130.

The PIC chip 300, which receives the optical signal through the first waveguide 130, may convert the optical signal into an electrical signal through the photonic component 330_P connected to the second waveguide 330 and may transmit the converted electrical signal to the EIC chip 400 through the second through via 300_V and/or the redistribution layer RDL.

The second waveguide 330 and the photonic component 330_P may be spaced apart from the EIC chip 400 with the second substrate 310 therebetween. Accordingly, the failure of the photonic component 330_P because of heat generated by the EIC chip 400 may be restricted.

In some embodiments, a bonding layer BL may be arranged between the PIC chip 300 and the package substrate 100. The bonding layer BL may be surrounded by the first molding layer ML1. The bonding layer BL may include a bonding pad BL_P (e.g., a plurality of bonding pads BL_P) and a bonding insulating layer BL_D surrounding the bonding pad BL_P. In some embodiments, the bonding pad BL_P may be electrically connected to conductive components of the second wiring structure 320 of the PIC chip 300 and the first wiring structure 120 of the package substrate 100.

In some embodiments, the bonding pad BL_P may be formed as a lower pad of the PIC chip 300 and an upper pad of the package substrate 100 diffusion-bonded to each other through heat. In the process of forming the bonding pad BL_P, the bonding insulating layer BL_D may be formed as an insulating layer surrounding the lower pad of the PIC chip 300, which is diffusion-bonded to an insulating layer surrounding the upper pad of the package substrate 100 through heat.

Therefore, the PIC chip 300 and the package substrate 100 may be electrically bonded to each other through hybrid bonding. However, the embodiments are not limited thereto, and the PIC chip 300 and the package substrate 100 may be electrically connected to each other by a connection terminal, such as a solder ball or a conductive film, such as an anisotropic film (ACF) or a non-conductive film (NCF). In some embodiments, the bonding insulating layer BL_D may include an encapsulation material including transparent epoxy that transmits an optical signal.

The first molding layer ML1 may be arranged on the package substrate 100 and surround the PIC chip 300. For example, the first molding layer ML1 may protect the PIC chip 300 from the outside.

The PIC chip 300 may be buried in the first molding layer ML1, and all of the side surfaces of the PIC chip 300 may be covered by the first molding layer ML1. The second waveguide 330 of the PIC chip 300 may not be exposed to the outside of the semiconductor package 1000. In some embodiments, the upper surface of the first molding layer ML1 may be coplanar with the upper surface of the PIC chip 300.

In some embodiments, the first molding layer ML1 may include or be formed of epoxy resin, polyimide resin, or the like. The first molding layer ML1 may be, for example, an epoxy mold compound (EMC).

In some embodiments, the semiconductor package 1000 may include a through electrode ML1_V penetrating the first molding layer ML1. The through electrode ML1_V may be electrically connected to the package substrate 100. For example, the through electrode ML1_V may transmit power to the EIC chip 400, the semiconductor chip 500, and the stack structures 200. For example, the through electrode ML_V may include a conductive material, for example, copper (Cu), aluminum (Al), silver (Ag), tin (Sn), gold (Au), nickel (Ni), lead (Pb), titanium (Ti), or an alloy thereof.

In some embodiments, the semiconductor package 1000 may further include the redistribution layer RDL. The redistribution layer RDL may be arranged on the PIC chip 300 and the first molding layer ML1. The stack structures 200, the semiconductor chip 500, and the EIC chip 400 may be arranged on the redistribution layer RDL.

The redistribution layer RDL may electrically connect the PIC chip 300, the stack structures 200, the semiconductor chip 500, and the EIC chip 400 to each other. For example, the redistribution layer RDL may electrically connect the PIC chip 300 to the EIC chip 400, the EIC chip 400 to the semiconductor chip 500, and the semiconductor chip 500 to the stack structures 200. The outer side surface of the redistribution layer RDL may be coplanar with the outer side surface of the first molding layer ML1 and the outer side surface of the package substrate 100.

The redistribution layer RDL may include the redistribution pattern RP and the redistribution insulating layer RD surrounding the same. The redistribution insulating layer RD may include or be formed of an insulating material, for example, photo imageable dielectric (PID) resin. In some embodiments, the redistribution insulating layer RD may further include an inorganic filler. In some embodiments, the redistribution insulating layer RD may have a multilayered structure in which redistribution patterns are arranged at respective layers.

The redistribution pattern RP may include the redistribution lines RL extending in the horizontal direction and the redistribution vias RV extending from the redistribution lines RL in the vertical direction (the Z direction). The redistribution lines RL may be arranged on at least one of the upper surface and the lower surface of the redistribution insulating layer RD or arranged inside the redistribution insulating layer RD. The redistribution vias RV may penetrate the redistribution insulating layer RD and be connected to the redistribution lines RL.

The redistribution pattern RP may include or be formed of a conductive material, for example, Cu, Al, Ag, Sn, Au, Ni, Pb, Ti, or an alloy thereof.

The stack structures 200 may be arranged on the first molding layer ML1 and the PIC chip 300. For example, the stack structures 200 may overlap the first molding layer ML1 and the PIC chip 300 in the vertical direction (the Z direction), respectively. For example, a portion of each stack structure 200 may overlap the first molding layer ML1 in the vertical direction (the Z direction), and another portion thereof may overlap the PIC chip 300 in the vertical direction (the Z direction).

In some embodiments, the stack structures 200 may be arranged on the redistribution layer RDL. For example, the stack structures 200 may be electrically connected to the semiconductor chip 500 through the redistribution layer RDL.

The stack structures 200, also described as a chip stack structure, or a semiconductor chip stack structure, may be spaced apart from each other in the horizontal direction. For example, the stack structures 200 may be arranged to surround the semiconductor chip 500 and the EIC chip 400. In some embodiments, the stack structures 200 may be arranged in a U shape. For example, the semiconductor chip 500 and the EIC chip 400 may be arranged in a region surrounded by the stack structures 200.

In some embodiments, the stack structures 200 and the EIC chip 400 may be located above edge regions of the package substrate 100 (e.g., adjacent to edges of the package substrate 100 when viewed from a plan view), and the semiconductor chip 500 may be located above the central region of the package substrate 100.

Each stack structure 200 may include a buffer chip 210, a plurality of core chips 220, and a core molding layer 230. The buffer chip 210 may be located on the lowermost portion of the stack structure 200, and the core chips 220 may be stacked on the buffer chip 210 in the vertical direction (the Z direction). The core molding layer 230 may be arranged on the buffer chip 210 and surround the core chips 220. For example, the upper surface of the core molding layer 230 may be coplanar with an upper surface of an uppermost core chip 220U. Accordingly, the upper surface of the uppermost core chip 220U may be externally exposed.

The buffer chip 210 and the core chips 220 may each include or be formed of, for example, a semiconductor material such as Si or Ge. Alternatively, each core chip 220 may include a compound semiconductor material, such as silicon carbide (SiC), gallium arsenide (GaAs), indium arsenide (InAs), or indium phosphide (InP).

The buffer chip 210 and the core chips 220 may each include an active surface and an inactive surface opposite thereto. On the active surface of each of the buffer chip 210 and the core chips 220, a semiconductor device including a variety of individual devices may be formed. The buffer chip 210 and the core chips 220 may each include a conductive region, for example, a well doped with impurities. The buffer chip 210 and the core chips 220 may each have a device isolation structure, such as a shallow trench isolation (STI) structure.

The individual devices of the buffer chip 210 may include various microelectronic devices, for example, a metal-oxide-semiconductor field effect transistor (MOSFET) such as a complementary metal-insulator-semiconductor (CMOS) transistor, an image sensor such as system large scale integration (LSI) or a CMOS imaging sensor (CIS), a micro-electro-mechanical system (MEMS), active elements, passive elements, and the like.

The individual devices of each core chip 220 may include a memory cell. For example, the memory cell may be a non-volatile memory cell, such as flash memory, phase-change random access memory (PRAM), magneto-resistive random access memory (MRAM), ferroelectric random access memory (FeRAM), or resistive random access memory (RRAM). In some embodiments, the memory cell may be a volatile memory cell, such as dynamic random access memory (DRAM) or static random access memory (SRAM).

The individual devices of the buffer chip 210 may be electrically connected to a conductive region 212 of the buffer chip 210, and the individual devices of each core chip 220 may be electrically connected to a conductive region of each core chip 220. For example, the conductive region 212 of the buffer chip 210 may include a conductive pattern 2121 and an insulating layer 2122 surrounding the conductive pattern 2121. For example, the conductive region of each core chip 220 may be substantially the same as that of the buffer chip 210.

In some embodiments, the buffer chip 210 may be a semiconductor chip including a serial-parallel conversion circuit and used to control the core chips 220, and the core chips 220 may each be a memory chip including memory cells. For example, the stack structure including the buffer chip 210 and the core chips 220 may be high bandwidth memory (HBM), the buffer chip 210 may be referred to as a HBM controller die, and each core chip 220 may be referred to as a DRAM die.

In some embodiments, a core chip that is the uppermost among the core chips 220 may be referred to as an uppermost core chip 220U. FIG. 2 shows that four core chips are stacked in each stack structure 200, but the number of core chips included in the stack structures 200 is not limited thereto.

In some embodiments, each core chip 220 except the uppermost core chip 220U among the core chips 220 may further include the through via 220_V extending from the upper surface of the core chip to the inside thereof. The through via 220_V of each core chip 220 may be electrically connected to the conductive region of each core chip 220. However, the embodiments are not limited thereto, and the uppermost core chip 220U may also include the through via 220_V.

Each core chip 220 may be electrically connected to a neighboring core chip or the buffer chip 210 through the through via 220_V. Accordingly, the core chips 220 may be electrically connected to the package substrate 100 through the through vias 220_V. For example, the conductive region of the uppermost core chip 220U may be electrically connected to the package substrate 100 through the through vias 220_V of the core chips 220 stacked under the uppermost core chip 220U.

In some embodiments, a thickness of each core chip 220, that is, a length thereof in the vertical direction (the Z direction), may be between about 20 μm and about 80 μm. The thicknesses of the core chips 220 may be substantially the same.

In some embodiments, a lower pad 280 may be located on the lower surface of the buffer chip 210. The lower pad 280 of the buffer chip 210 may be electrically connected to the through via 210_V or the conductive region 212 of the buffer chip 210.

The lower pad 280 of the buffer chip 210 may be electrically connected to the redistribution layer RDL through a connection terminal CT2. However, the embodiments are not limited thereto, and the lower pad 280 of the buffer chip 210 may be electrically connected to the redistribution layer RDL through an ACF, an NCF, direct bonding, or hybrid bonding.

The EIC chip 400 may be arranged on the first molding layer ML1 and the PIC chip 300. For example, the EIC chip 400 may overlap the first molding layer ML1 and the PIC chip 300 in the vertical direction (the Z direction). For example, a portion of the EIC chip 400 may overlap the first molding layer ML1 in the vertical direction (the Z direction), and another portion of the EIC chip 400 may overlap the PIC chip 300 in the vertical direction (the Z direction).

In some embodiments, the EIC chip 400 may be arranged on the redistribution layer RDL. For example, the EIC chip 400 may be electrically connected to the semiconductor chip 500 through the redistribution layer RDL.

The EIC chip 400 may include a third substrate 410 and a third wiring structure 420. The third substrate 410 of the EIC chip 400 may include an active surface 410_A and an inactive surface opposite thereto. The third wiring structure 420 may be formed on the active surface 410_A of the third substrate 410.

In some embodiments, the EIC chip 400 may be arranged on the redistribution layer RDL to make the active surface 410_A of the third substrate 410 face the redistribution layer RDL. For example, the EIC chip 400 may be arranged on the redistribution layer RDL in a face-down manner.

The third substrate 410 may include or be formed of a semiconductor material, such as Si. Alternatively, the third substrate 410 may include or be formed of a semiconductor material, such as Ge.

In some embodiments, the EIC chip 400 may include a plurality of individual devices used to interface the PIC chip 300 with the semiconductor chip 500. The individual devices of the EIC chip 400 may be on the active surface 410_A of the third substrate 410. For example, the EIC chip 400 may include CMOS drivers, trans-impedance amplifiers, and the like to perform a function of controlling high-frequency signaling of the PIC chip 300.

The third wiring structure 420 may include a third wiring pattern 421 and a third wiring insulating layer 422 surrounding the third wiring pattern 421. The third wiring pattern 421 may include third wiring lines 421_L extending in the horizontal direction and third wiring vias 421_V extending from the third wiring line 421_L in the vertical direction (the Z direction). The third wiring pattern 421 may be electrically connected to the individual devices.

The EIC chip 400 may further include a lower pad 480. The lower pad 480 may be on the lower surface of the third wiring structure 420 and electrically connected to the third wiring pattern 421.

The lower pad 480 of the EIC chip 400 may be electrically connected to the redistribution layer RDL through a connection terminal CT4. However, the embodiments are not limited thereto, and the lower pad 480 of the EIC chip 400 may be electrically connected to the redistribution layer RDL through an ACF, an NCF, direct bonding, or hybrid bonding.

The semiconductor chip 500 may be arranged on the PIC chip 300. In some embodiments, the PIC chip 300 and the semiconductor chip 500 may be located above the central region of the package substrate 100.

In some embodiments, the area of the semiconductor chip 500 may be less than that of the PIC chip 300, and the entirety of the semiconductor chip 500 may overlap the PIC chip 300 in the vertical direction (the Z direction). For example, all side surfaces of the semiconductor chip 500 may be arranged on the PIC chip 300 to vertically overlap the PIC chip 300 from a plan view. In some embodiments, the semiconductor chip 500 does not overlap the first molding layer ML1 in the vertical direction (the Z direction).

The semiconductor chip 500 may include a fourth substrate 510 and a fourth wiring structure 520. The fourth substrate 510 may include an active surface 510_A and an inactive surface opposite thereto. The fourth wiring structure 520 may be on the active surface 510_A of the fourth substrate 510. In some embodiments, the semiconductor chip 500 may include an application specific integrated circuit (ASIC).

In some embodiments, the semiconductor chip 500 may be arranged on the redistribution layer RDL to make the active surface 510_A of the fourth substrate 510 face the redistribution layer RDL. For example, the semiconductor chip 500 may be arranged on the redistribution layer RDL in a face-down manner.

In some embodiments, individual devices of various types may be located on the active surface 510_A of the fourth substrate 510. For example, the individual devices may include various microelectronic devices, for example, a CMOS transistor, a MOSFET, an image sensor such as system LSI or a CIS, a MEMS, active elements, passive elements, and the like.

The fourth wiring structure 520 may include a fourth wiring pattern 521 and a fourth wiring insulating layer 522 surrounding the fourth wiring pattern 521. The fourth wiring pattern 521 may include fourth wiring lines 521_L extending in the horizontal direction and fourth wiring vias 521_V extending from the fourth wiring line 521_L in the vertical direction (the Z direction).

In some embodiments, a lower pad 580 may be located on the lower surface of the semiconductor chip 500. The lower pad 580 of the semiconductor chip 500 may be electrically connected to the fourth wiring pattern 521 of the fourth wiring structure 520 of the semiconductor chip 500.

The lower pads 580 of the semiconductor chip 500 may be electrically connected to the redistribution layer RDL through a connection terminal CT5. However, the embodiments are not limited thereto, and the lower pads 580 of the semiconductor chip 500 may be electrically connected to the redistribution layer RDL through an ACF, an NCF, direct bonding, or hybrid bonding.

Referring to FIG. 4, the stack structures 200, the semiconductor chip 500, and the EIC chip 400 may be spaced apart from each other in the horizontal direction, for example, to have gaps therebetween. The PIC chip 300 may overlap all of the stack structures 200, the semiconductor chip 500, and the EIC chip 400 in the vertical direction (the Z direction).

In an embodiment, the PIC chip 300 may include an additional wiring structure (not shown) on the upper surface of the PIC chip 300, that is, the surface opposite the surface on which the second waveguide 330 is located, and thus, the stack structures 200, the semiconductor chip 500, and the EIC chip 400 may be electrically connected to each other. As the signal distance between the semiconductor chip 500 and the EIC chip 400 relatively shortens, the signal reliability may be improved.

In some embodiments, when the semiconductor package 1000 further includes the redistribution layer RDL, the stack structures 200, the semiconductor package 500, and the EIC chip 400 may be electrically connected to each other through the redistribution layer RDL. Accordingly, the semiconductor chip 500 may be electrically connected to the EIC chip 400 without needing a separate through via, reducing the signal distance between the semiconductor chip 500 and the EIC chip 400 and improving signal reliability.

Referring back to FIG. 2, the second molding layer ML2 may be located on the first molding layer ML1 or the redistribution layer RDL and may surround the stack structures 200, the semiconductor chip 500, and the EIC chip 400. For example, the second molding layer ML2 may at least protect the stack structures 200, the semiconductor chip 500, and the EIC chip 400 from the outside.

In some embodiments, the upper surface of the second molding layer ML2 may be coplanar with the upper surface of each stack structure 200, the upper surface of the semiconductor chip 500, and the upper surface of the EIC chip 400. For example, the upper surface of each stack structure 200, the upper surface of the semiconductor chip 500, and the upper surface of the EIC chip 400 may be externally exposed.

In some embodiments, the second molding layer ML2 may include or be formed of epoxy resin, polyimide resin, or the like. The second molding layer ML2 may be, for example, an EMC.

In some embodiments, an interface may exist between the second molding layer ML2 and a core molding layer 230 of each stack structure 200. For example, because of differences in curing timings between the core molding layers 230 and the second molding layer ML2, interfaces may exist between the core molding layers 230 and the second molding layer ML2, respectively.

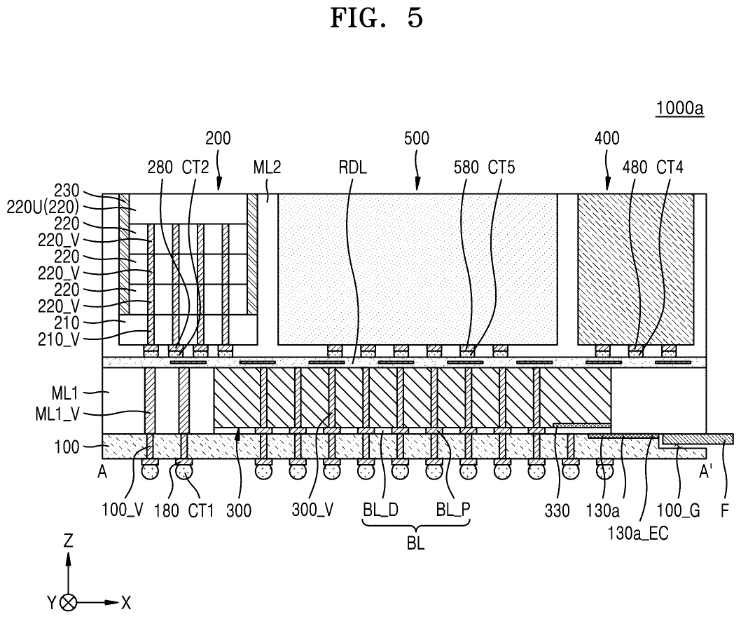

FIG. 5 is a schematic cross-sectional view of a semiconductor package 1000a according to an embodiment, taken along the line A-A′ of FIG. 1.

Most of the components forming the semiconductor package 1000a described below and the materials of the components are substantially the same as or similar to those described above with reference to FIG. 2. Therefore, for convenience of explanation, differences between the semiconductor package 1000a of FIG. 5 and the aforementioned semiconductor package 1000 of FIG. 2 are mainly described.

The semiconductor package 1000a may further include optical fiber F. The optical fiber F may be configured to transmit optical signals from an external source of the semiconductor package 1000a to the first waveguide 130a of the package substrate 100.

The package substrate 100 may include a first groove 100_G. The first groove 100_G may be recessed inwards from the upper and side surfaces of the package substrate 100. For example, the inside of the first groove 100_G may be open towards the side surface and the upper surface of the package substrate 100. In some embodiments, the first groove 100_G may be referred to as a V-groove.

In some embodiments, the first groove 100_G may be adjacent to the first waveguide 130a. For example, an end portion of the first waveguide 130a may be exposed to the outside through the first groove 100_G. For example, the vertical level of the bottom surface of the first groove 100_G may be lower than that of the first waveguide 130a.

In some embodiments, the optical fiber F may be attached into the first groove 100_G. For example, the optical fiber F may be attached to the inside of the first groove 100_G by a clear adhesive member located between the package substrate 100 and the optical fiber F. In some embodiments, the optical fiber F may be a fiber array unit (FAU).

In some embodiments, the optical fiber F may face an end portion of the first waveguide 130a. The vertical level of the optical fiber F may be the same as that of the first waveguide 130a. The optical fiber F may be optically connected to the first waveguide 130a. For example, the first waveguide 130a may further include an edge coupler 130a_EC located on the end portion of the first waveguide 130a that faces the optical fiber F. The optical fiber F may be optically connected to the first waveguide 130a through the edge coupler 130a_EC.

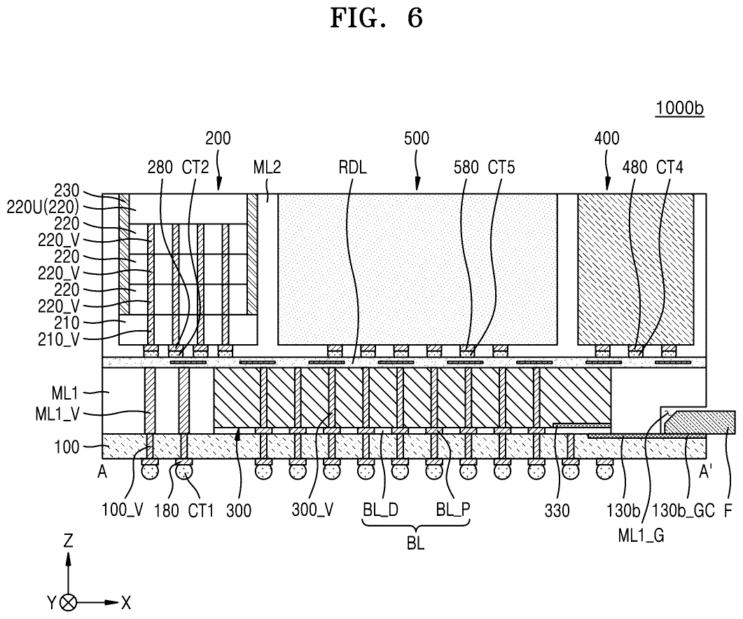

FIG. 6 is a schematic cross-sectional view of a semiconductor package 1000b according to an embodiment, taken along the line A-A′ of FIG. 1.

Most of the components forming the semiconductor package 1000b described below and the materials of the components are substantially the same as or similar to those described above with reference to FIG. 2. Therefore, for convenience of explanation, differences between the semiconductor package 1000b of FIG. 6 and the aforementioned semiconductor package 1000 of FIG. 2 are mainly described.

The semiconductor package 1000b may further include optical fiber F. The optical fiber F may be configured to transmit optical signals from an external source of the semiconductor package 1000b to a first waveguide 130b of the package substrate 100.

The first molding layer ML1 may include a second groove ML1_G. The second groove ML1_G may be recessed inwards from the lower and side surfaces of the first molding layer ML1. The second groove ML1_G may be located above the first waveguide 130b.

A portion of the first waveguide 130b may be exposed to the outside through the second groove ML1_G. For example, a grating coupler 130b_GC may be located on the portion of the first waveguide 130b, which is externally exposed through the second groove ML1_G.

In some embodiments, the optical fiber F may be located inside the second groove ML1_G. The optical fiber F may be located above the first waveguide 130b. For example, the vertical level of the optical fiber F may be higher than that of the first waveguide 130b. In some embodiments, the optical fiber F may be fixed to the inside of the second groove ML1_G by a clear adhesive member located between the optical fiber F and the first molding layer.

In some embodiments, the optical fiber F may face the first waveguide 130b. For example, the grating coupler 130b_GC of the first waveguide 130b may face the optical fiber F. For example, the optical fiber F may be optically connected to the first waveguide 130b through the grating coupler 130b_GC.

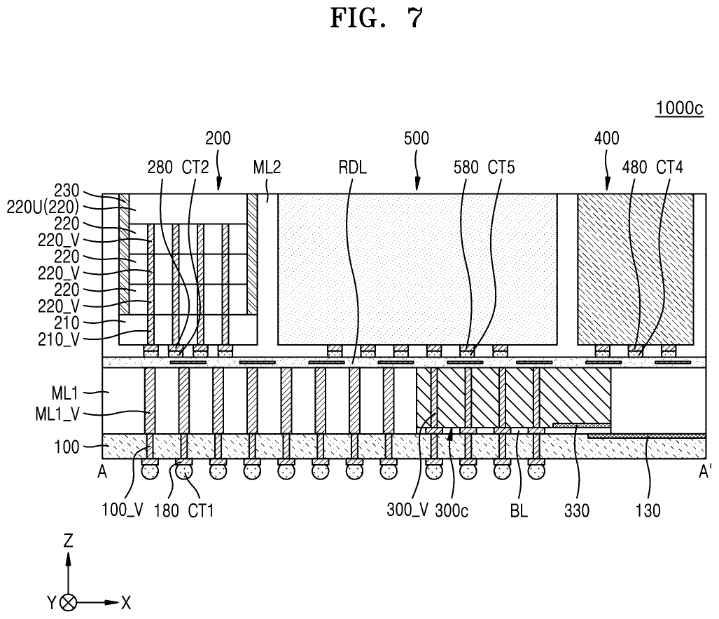

FIG. 7 is a schematic cross-sectional view of a semiconductor package 1000c according to an embodiment, taken along the line A-A′ of FIG. 1.

Most of the components forming the semiconductor package 1000c described below and the materials of the components are substantially the same as or similar to those described above with reference to FIG. 2. Therefore, for convenience of explanation, differences between the semiconductor package 1000c of FIG. 7 and the aforementioned semiconductor package 1000 of FIG. 2 are mainly described.

The semiconductor package 1000c may include a PIC chip 300c. The PIC chip 300c may overlap the semiconductor chip 500 and the EIC chip 400 in the vertical direction (the Z direction).

For example, the area of the PIC chip 300c may be less than that of the semiconductor chip 500. A portion of the semiconductor chip 500 may be located above the PIC chip 300c to vertically overlap the PIC chip 300c, and another portion of the semiconductor chip 500 may be located above the first molding layer ML1 and may not vertically overlap the PIC chip 300c.

In some embodiments, the semiconductor chip 500 may be electrically connected to the EIC chip 400 through a wiring structure arranged on the upper surface of the PIC chip 300c. In some embodiments, the semiconductor chip 500 may be electrically connected to the EIC chip 400 through the redistribution layer RDL arranged on the PIC chip 300c and the first molding layer ML1.

In some embodiments, the stack structures 200 may be arranged on the first molding layer ML1. For example, the PIC chip 300c may not overlap the stack structures 200 in the vertical direction (the Z direction). For example, the stack structures 200 may be arranged on the redistribution layer RDL and thus be electrically connected to the semiconductor chip 500 through the redistribution layer RDL.

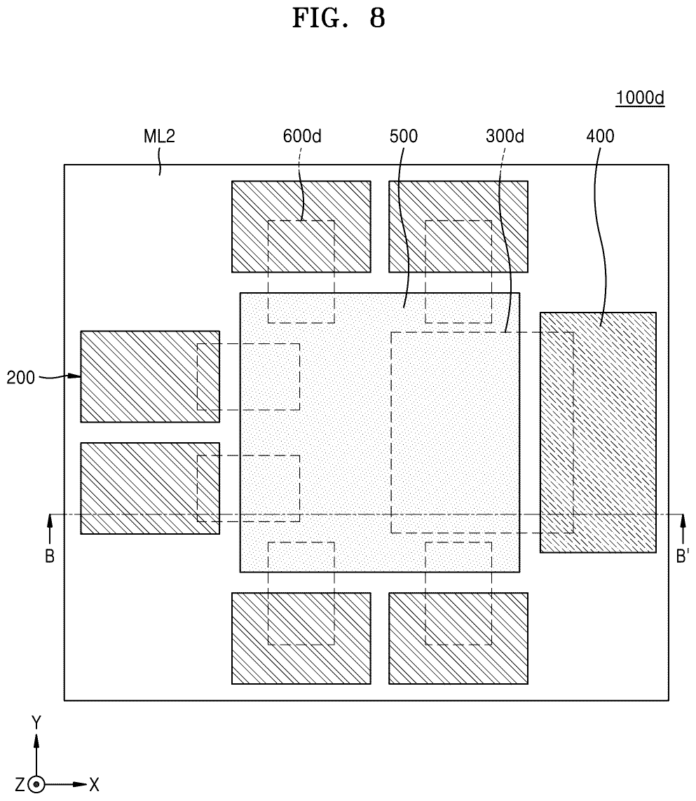

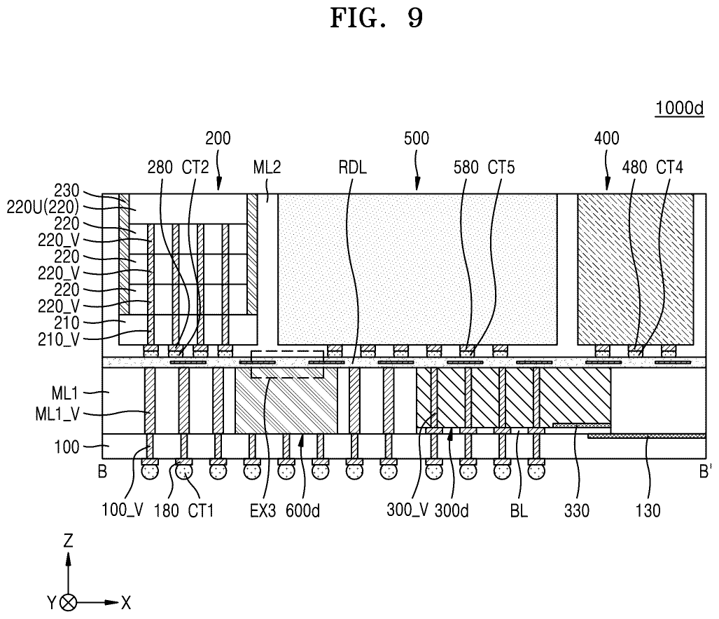

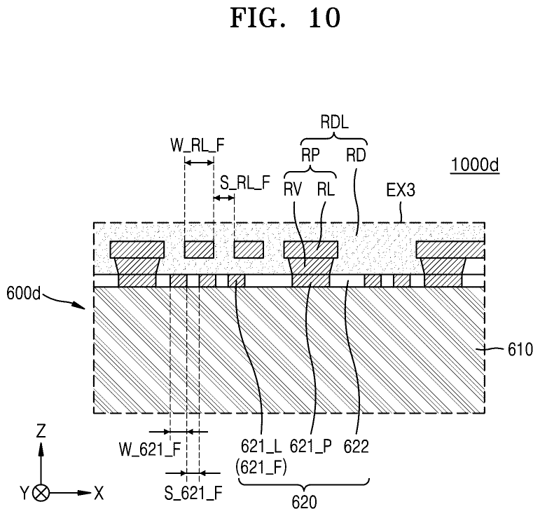

FIG. 8 is a schematic plan view of a semiconductor package 1000d according to an embodiment. FIG. 9 is a schematic cross-sectional view of the semiconductor package 1000d of FIG. 8, taken along a line B-B′ of FIG. 8. FIG. 10 is an enlarged schematic cross-sectional view of a region EX3 of the semiconductor package 1000d of FIG. 8.

Most of the components forming the semiconductor package 1000d described below and the materials of the components are substantially the same as or similar to those described above with reference to FIG. 7. Therefore, for convenience of explanation, differences between the semiconductor package 1000d of FIG. 8 and the aforementioned semiconductor package 1000c of FIG. 7 are mainly described.

The semiconductor package 1000d may further include a plurality of bridge chips 600d. Each bridge chip 600d may overlap the semiconductor chip 500 and one of the stack structures 200 in the vertical direction (the Z direction). In some embodiments, the bridge chips 600d may be in one-to-one correspondence with the stack structures 200. The PIC chip 300d may overlap the semiconductor chip 500 and the EIC chip 400 in the vertical direction (the Z direction).

The bridge chips 600d may be spaced apart from the PIC chip 300d in the horizontal direction. For example, the first molding layer ML1 and the through electrode ML1_V may be located between each bridge chip 600d and the PIC chip 300d. The first molding layer ML1 may surround the bridge chips 600d and the PIC chip 300d.

The redistribution layer RDL may be arranged on the first molding layer ML1, the bridge chips 600d, and the PIC chip 300d. The area of the PIC chip 300d may be less than that of the semiconductor chip 500. The bridge chips 600d may electrically connect the semiconductor chip 500 to one of the stack structures 200 spaced apart from each other in the horizontal direction. In some embodiments, the redistribution pattern RP of the redistribution layer RDL, which is electrically connected to one of the stack structures 200, may be electrically connected to the redistribution pattern RP of the redistribution layer RDL, which is electrically connected to the semiconductor chip 500, through the bridge chip 600d.

The bridge chip 600d may include a bridge substrate 610 and a bridge wiring structure 620. The bridge wiring structure 620 may include a bridge line 621_L, a bridge pad 621_P, and a bridge insulating layer 622. The bridge pad 621_P may contact the redistribution pattern RP of the redistribution layer RDL, the bridge line 621_L may extend on the upper surface of the bridge substrate 610 in the horizontal direction, and the bridge insulating layer 622 may surround the bridge line 621_L and the bridge pad 621_P. For example, the bridge pad 621_P may be a portion of the bridge line 621_L that contacts the redistribution pattern RP. Redistribution lines RL that are not electrically connected in the redistribution layer RDL from among the redistribution lines RL may be electrically connected through the bridge chip 600d.

In some embodiments, a line with the smallest line width among the bridge lines 621_L may be referred to as a fine bridge line 621_F, and the minimum distance between two adjacent bridge lines 621_L may be referred to as a bridge line distance S_621_F. A line with the smallest line width among the redistribution lines RL may be referred to as a fine redistribution line, and the minimum distance between two adjacent redistribution lines RL may be referred to as a redistribution line distance S_RL_F.

A line width W_621_F of the fine bridge line 621_F may be less than a line width W_RL_F of the fine redistribution line. The distance of the bridge line distance S_621_F may be less than the distance of the redistribution line distance S_RL_F. In some embodiments, the line width W_RL_F of the fine redistribution line may be about 25 μm or less, and the redistribution line distance S_RL_F may be about 25 μm or less. The line width W_621_F of the fine bridge line 621_F may be about 9 μm or less, and the redistribution line distance S_RL_F may be about 12 μm or less. For example, the line width W_RL_F of the fine redistribution line may be in a range of about 15 μm to about 25 μm, the redistribution line distance S_RL_F may be in a range of about 15 μm to about 25 μm, the line width W_621_F of the fine bridge line 621_F may be in a range of about 3 μm to about 9 μm, and the bridge line distance S_621_F may be in a range of about 3 μm to about 12 μm.

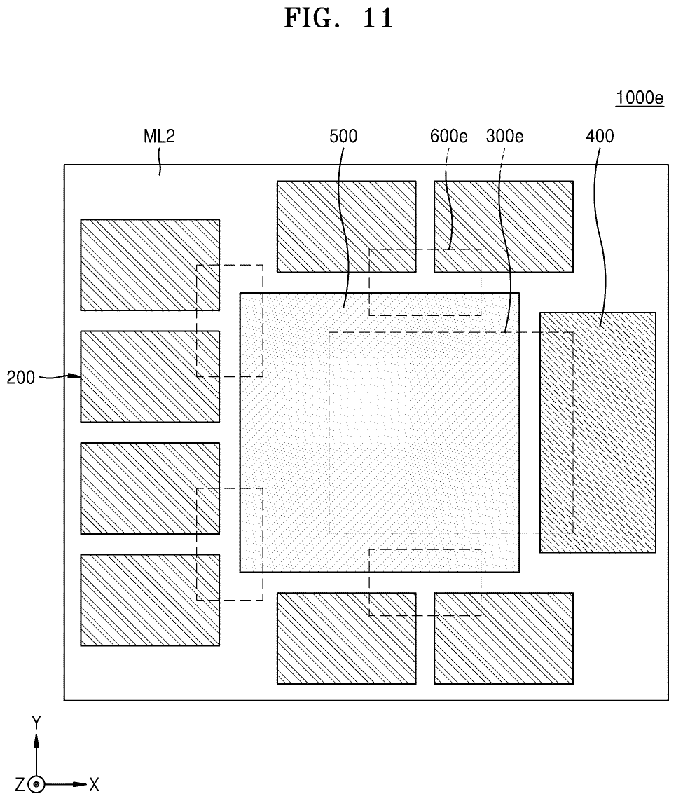

FIG. 11 is a schematic plan view of a semiconductor package 1000e according to an embodiment.

Most of the components forming the semiconductor package 1000e described below and the materials of the components are substantially the same as or similar to those described above with reference to FIG. 8. Therefore, for convenience of explanation, differences between the semiconductor package 1000e of FIG. 11 and the aforementioned semiconductor package 1000d of FIG. 8 are mainly described.

The semiconductor package 1000e may further include a plurality of bridge chips 600e. Each bridge chip 600e may vertically overlap at least two stack structures and the semiconductor chip 500. For example, at least two of the stack structures may be arranged on one bridge chip 600e.

Each bridge chip 600e may be spaced apart from the PIC chip 300e in the horizontal direction, and the first molding layer (ML1, see FIG. 2) may surround the bridge chips 600e and the PIC chip 300e. The area of the PIC chip 300e may be less than that of the semiconductor chip 500.

In some embodiments, the bridge chips 600e may each be arranged under two stack structures and the semiconductor chip 500. Each bridge chip 600e may electrically connect two stack structures to the semiconductor chip 500. For example, the number of bridge chips 600e may be less than the number of stack structures 200. For example, the number of bridge chips 600e may be half the number of stack structures 200. However, the number of stack structures 200 arranged on the bridge chip 600e is not limited thereto.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Also these spatially relative terms such as “above” and “below” as used herein have their ordinary broad meanings—for example element A can be above element B even if when looking down on the two elements there is no overlap between them (just as something in the sky is generally above something on the ground, even if it is not directly above).

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate including a first waveguide;
a photonic integrated circuit (PIC) chip on the package substrate and including a second waveguide;
a first molding layer on the package substrate and surrounding the PIC chip;
an electronic integrated circuit (EIC) chip arranged on the first molding layer and the PIC chip to vertically overlap both the first molding layer and the PIC chip;
a semiconductor chip on the PIC chip; and
a plurality of stack structures arranged horizontally apart from each other on the first molding layer and the PIC chip,
wherein the first waveguide is disposed on an upper surface of the package substrate, and
wherein the PIC chip is arranged on the package substrate such that a surface of the PIC chip, adjacent to the second waveguide, faces the package substrate.

2. The semiconductor package of claim 1, wherein:
the EIC chip, the semiconductor chip, and the plurality of stack structures are spaced apart from each other in a horizontal direction, and
each of the EIC chip, the semiconductor chip, and the plurality of stack structures overlaps the PIC chip in a vertical direction.

3. The semiconductor package of claim 2, wherein:
the semiconductor chip is located above a central region of the package substrate, and
the plurality of stack structures and the EIC chip are located above edge regions of the package substrate.

4. The semiconductor package of claim 3, wherein:
an area of the PIC chip is greater than an area of the semiconductor chip, and
all side surfaces of the semiconductor chip are arranged on the PIC chip to overlap the PIC chip in a vertical direction.

5. The semiconductor package of claim 1, wherein:
the PIC chip is configured to convert an optical signal into an electrical signal and an electrical signal into an optical signal, and
the EIC chip is configured to interface the PIC chip with the semiconductor chip.

6. The semiconductor package of claim 1, wherein a portion of the second waveguide overlaps a portion of the first waveguide in a vertical direction and faces the portion of the first waveguide.

7. The semiconductor package of claim 6, wherein:
the package substrate comprises a groove that is recessed inward from an upper surface and a side surface of the package substrate, and
an end portion of the first waveguide is exposed to the outside of the semiconductor package through the groove.

8. The semiconductor package of claim 6, wherein:
the PIC chip is buried inside the first molding layer, and
the first waveguide extends to an outer periphery of the PIC chip.

9. The semiconductor package of claim 1, further comprising a redistribution layer arranged on the first molding layer and the PIC chip,
wherein the plurality of stack structures, the semiconductor chip, and the EIC chip are arranged on the redistribution layer, and
wherein the redistribution layer electrically connects the plurality of stack structures, the semiconductor chip, and the EIC chip to each other.

10. The semiconductor package of claim 9, wherein:
the PIC chip further comprises a through via extending from an upper surface of the PIC chip to a lower surface thereof, and
the through via is electrically connected to the redistribution layer.

11. The semiconductor package of claim 1, wherein the first molding layer further comprises a through electrode extending from an upper surface of the first molding layer to a lower surface of the first molding layer.

12. A semiconductor package comprising:
a package substrate including a first waveguide;
a photonic integrated circuit (PIC) chip on the package substrate and including a second waveguide;
a first molding layer on the package substrate and surrounding the PIC chip;
an electronic integrated circuit (EIC) chip arranged on the first molding layer and the PIC chip to vertically overlap both the first molding layer and the PIC chip;
a semiconductor chip arranged on the first molding layer and the PIC chip;
a plurality of stack structures arranged horizontally apart from each other on the first molding layer; and
a second molding layer arranged on the first molding layer and surrounding the plurality of stack structures, the semiconductor chip, and the EIC chip,
wherein:
the first waveguide of the package substrate is arranged adjacent to an upper surface of the package substrate,
the second waveguide of the PIC chip is arranged adjacent to a lower surface of the PIC chip, and
the PIC chip overlaps the semiconductor chip and the EIC chip in a vertical direction.

13. The semiconductor package of claim 12, wherein:
a portion of the first waveguide overlaps a portion of the second waveguide in a vertical direction and faces the portion of the second waveguide, and
the first waveguide is optically connected to the second waveguide.

14. The semiconductor package of claim 13, wherein the second molding layer is recessed inwards from a lower surface and a side surface of the second molding layer and comprises a groove located above the first waveguide.

15. The semiconductor package of claim 12, further comprising a redistribution layer arranged on the PIC chip and the first molding layer,
wherein the redistribution layer electrically connects the plurality of stack structures, the semiconductor chip, and the EIC chip to each other.

16. The semiconductor package of claim 12, further comprising a bridge chip arranged on the package substrate and spaced apart from the PIC chip in a horizontal direction,
wherein the first molding layer surrounds the PIC chip and the bridge chip, and
wherein the bridge chip overlaps the semiconductor chip and at least one of the plurality of stack structures in a vertical direction.

17. The semiconductor package of claim 16, further comprising a redistribution layer arranged on the PIC chip, the bridge chip, and the first molding layer,
wherein a line width of a fine bridge line of the bridge chip is less than a line width of a fine redistribution line of the redistribution layer.

18. A semiconductor package comprising:
a package substrate including a first waveguide;
a photonic integrated circuit (PIC) chip on the package substrate and including a second waveguide;
a first molding layer on the package substrate and surrounding the PIC chip;
a redistribution layer on the PIC chip and the first molding layer;
an electronic integrated circuit (EIC) chip on the redistribution layer;
a semiconductor chip on the redistribution layer and spaced apart from the EIC chip in a horizontal direction; and
a plurality of stack structures arranged on the redistribution layer and spaced apart from the EIC chip and the semiconductor chip in a horizontal direction,
wherein:
the first waveguide is disposed adjacent to an upper surface of the package substrate,
the second waveguide is disposed on a lower surface of the PIC chip,
a portion of the first waveguide faces a portion of the second waveguide, and
the plurality of stack structures and the EIC chip are arranged to surround the semiconductor chip.

19. The semiconductor package of claim 18, wherein the PIC chip overlaps the EIC chip, the semiconductor chip, and the plurality of stack structures in a vertical direction.

20. The semiconductor package of claim 18, wherein:
the semiconductor package further comprises a plurality of bridge chips,
the PIC chip overlaps the semiconductor chip and the EIC chip in a vertical direction, and
each of the plurality of bridge chips vertically overlaps the semiconductor chip and at least one of the plurality of stack structures.
